(19) United States
(12) Patent Application Publication
(10) Pub. No.: US 2026/0150217 A1
(43) Pub. Date: May 28, 2026

(54) ELECTRONIC ASSEMBLY AND ELECTRONIC APPARATUS

(71) Applicant: Wiwynn Corporation, New Taipei City (TW)

(72) Inventors: Jing-Suei Gao, New Taipei City (TW); Yong-Yuan Yang, New Taipei City (TW)

(73) Assignee: Wiwynn Corporation, New Taipei City (TW)

(21) Appl. No.: 19/284,706

(22) Filed: Jul. 30, 2025

(30) Foreign Application Priority Data
Nov. 26, 2024 (TW) 113145528

(51) Int. Cl. H05K 7/14; G06F 1/18

(52) U.S. Cl. CPC H05K 7/1488; G06F 1/183

(57) ABSTRACT

An electronic assembly for being installed in a housing of an electronic apparatus is provided. The electronic assembly includes an electronic device, a limiting component and a fixing component. The fixing component includes a stop structure. The stop structure protrudes from a surface of the fixing component perpendicularly to a first direction. When the electronic device is installed in the housing along the first direction and is in a fixed position, the limiting component is partially embedded in the electronic device and partially embedded in the housing, and the stop structure stops the electronic device from leaving the housing along a second direction opposite to the first direction.

### BACKGROUND OF THE INVENTION

### 1. Field of the Invention

The present disclosure relates to an electronic assembly and an electronic apparatus, and more particularly, to an electronic assembly which is easy to assemble and disassemble and an electronic apparatus including the same.

### 2. Description of the Prior Art

With the vigorous development of cutting-edge technologies, such as Internet of Things, edge computing and artificial intelligence, electronic apparatus with a huge information processing capability plays an indispensable role. In general, a plurality of different and/or identical electronic devices can be installed in a housing or a rack of an electronic apparatus to achieve the desired functions. Taking a server as an example, the server includes different electronic devices, such as motherboards, central processing units (CPU), memories, chips, hard disk, network cards, power supplies, fans, etc., and thus can provide a powerful computing capability and load a large amount of stored data to meet the needs of users.

The conventional method to fix the electronic device to the housing or the rack of the electronic apparatus includes using screws to lock the electronic device to the housing of the electronic apparatus or to an exclusive housing for the electronic device provided by the electronic apparatus. However, the screws may get stripped, and the electronic device may be damaged thereby. In addition, in order to provide a stable locking relationship, an electronic device often requires multiple screws to provide the locking function. When the number of electronic devices is increased, multiple locking steps are required, which significantly increases the time required to assemble and maintain the electronic apparatus. Therefore, how to improve the method for installing the electronic devices to the electronic apparatus, so as to reduce the probability of damaging the electronic devices and save the time required for assembling and maintaining the electronic apparatus, is a goal of relevant industries.

### SUMMARY OF THE INVENTION

According to an embodiment of the present disclosure, an electronic assembly for being installed in a housing of an electronic apparatus is provided. The electronic assembly includes an electronic device, a limiting component and a fixing component. The fixing component includes a stop structure. The stop structure protrudes from a surface of the fixing component perpendicularly to a first direction. When the electronic device is installed in the housing along the first direction and is in a fixed position, the limiting component is partially embedded in the electronic device and partially embedded in the housing, and the stop structure stops the electronic device from leaving the housing along a second direction opposite to the first direction.

According to another embodiment of the present disclosure, an electronic apparatus includes a housing and an electronic assembly. The electronic assembly is installed in the housing. The electronic assembly includes an electronic device, a limiting component and a fixing component. The fixing component includes a stop structure. The stop structure protrudes from a surface of the fixing component perpendicularly to a first direction. When the electronic device is installed in the housing along the first direction and is in a fixed position, the limiting component is partially embedded in the electronic device and partially embedded in the housing, and the stop structure stops the electronic device from leaving the housing along a second direction opposite to the first direction.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a three-dimensional schematic view of an electronic assembly and a housing in an assembling state according to an embodiment of the present disclosure.

FIG. 2 is an exploded schematic view of the electronic assembly and the housing in FIG. 1.

FIG. 3 is a partially exploded schematic view of the electronic assembly in FIG. 1 to illustrate the assembly of the electronic assembly.

FIG. 4 is a three-dimensional schematic view of the electronic assembly in FIG. 1.

FIG. 5 is a schematic view showing the electronic assembly and the housing in FIG. 1 in a separated state to illustrate the assembly of the electronic assembly and the housing.

FIG. 6 is an enlarged cross-sectional schematic view taken along line A-A′ in FIG. 1.

FIG. 7 is a three-dimensional schematic view of a limiting component in FIG. 1.

FIG. 8 is a three-dimensional schematic view of an electronic assembly and a housing in an assembling state according to another embodiment of the present disclosure.

FIG. 9 is an exploded schematic view of the electronic assembly and the housing in FIG. 8.

FIG. 10 is a partially exploded schematic view of the electronic assembly and the housing in FIG. 8 to illustrate the assembly of the electronic assembly and the housing.

FIG. 11 is a three-dimensional schematic view of an electronic apparatus according to yet another embodiment of the present disclosure.

### DETAILED DESCRIPTION

In the following detailed description of the embodiments, reference is made to the accompanying drawings which form a part thereof, and in which is shown by way of illustration specific embodiments in which the disclosure may be practiced. In this regard, directional terminology, such as up, down, left, right, front, back, bottom or top is used with reference to the orientation of the Figure(s) being described. The elements of the present disclosure can be positioned in a number of different orientations. As such, the directional terminology is used for purposes of illustration and is in no way limiting. In addition, identical numeral references or similar numeral references are used for identical elements or similar elements in the following embodiments.

Hereinafter, for the description of “the first feature is formed on or above the second feature”, it may refer that “the first feature is in contact with the second feature directly”, or it may refer that “there is another feature between the first feature and the second feature”, such that the first feature is not in contact with the second feature directly.

It is understood that, although the terms first, second, etc. may be used herein to describe various elements, regions, layers and/or sections, these elements, regions, layers and/or sections should not be limited by these terms. These terms may be only used to distinguish one element, region, layer and/or section from another element, region, layer and/or section. Terms such as “first,” “second,” and other numerical terms when used herein do not imply a sequence or order unless clearly indicated by the context. Thus, a first element, region, layer and/or section discussed below could be termed a second element, region, layer and/or section without departing from the teachings of the embodiments. The terms used in the claims may not be identical with the terms used in the specification, but may be used according to the order of the elements claimed in the claims.

In the present disclosure, some of the following drawings are described in conjunction with the XYZ Cartesian coordinate system for the sake of convenience. In the following description, the first direction is exemplified by the +Y direction, and the second direction is exemplified by the −Y direction. When a direction is perpendicular to the first direction or the second direction, the direction can be any direction on the XZ plane, such as the +X direction, the −X direction, the +Z direction, the −Z direction or other directions on the XZ plane.

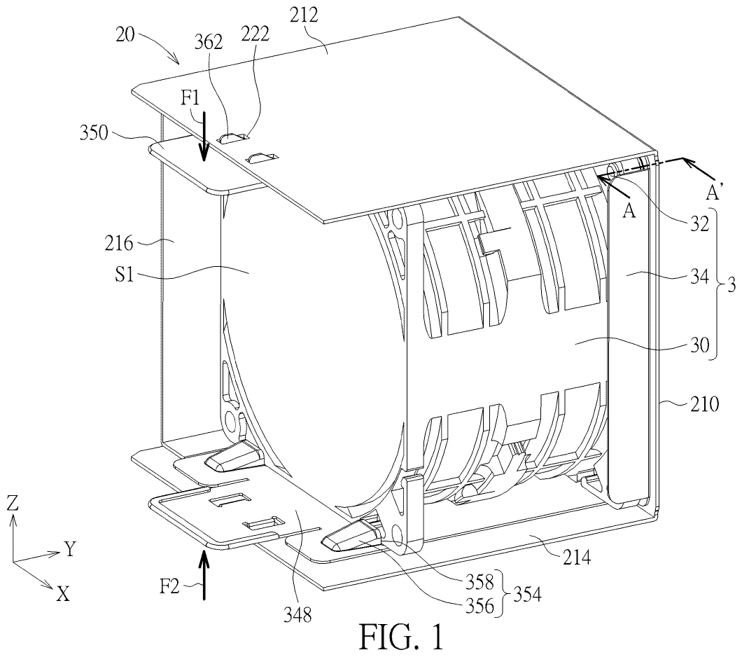

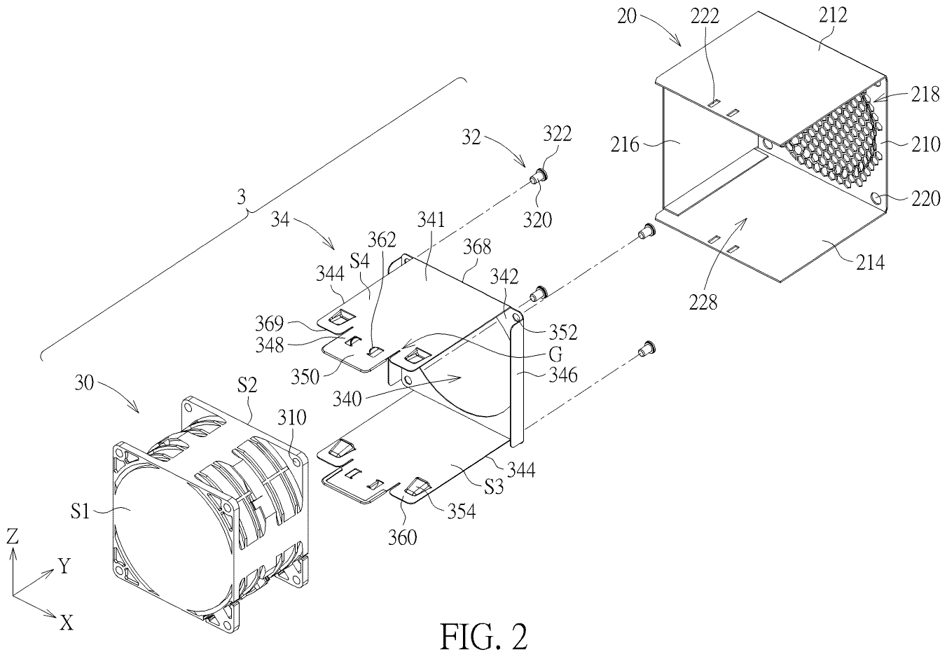

Please refer to FIG. 1 and FIG. 2. FIG. 1 is a three-dimensional schematic view of an electronic assembly 3 and a housing 20 in an assembling state according to an embodiment of the present disclosure. FIG. 2 is an exploded schematic view of the electronic assembly 3 and the housing 20 in FIG. 1. In the present disclosure, an electronic assembly 3 for being installed in a housing 20 of an electronic apparatus is provided. The electronic assembly 3 includes an electronic device 30, a limiting component 32 and a fixing component 34. The limiting component 32 may include a first portion 320 and a second portion 322 disposed sequentially along the first direction (herein, exemplified by the +Y direction). The fixing component 34 includes a stop structure 354. The stop structure 354 protrudes from the surface S3 of the fixing component 34 perpendicularly to the first direction (herein, exemplified by protruding along a direction parallel to the Z direction). When the electronic device 30 is installed in the housing 20 along the first direction and is in a fixed position, as shown in FIG. 1, the first portion 320 of the limiting component 32 is embedded in the electronic device 30, the second portion 322 of the limiting component 32 is embedded in the housing 20, and the stop structure 354 stops the electronic device 30 from leaving the fixing component 34 along a second direction (herein, exemplified by the −Y direction) opposite to the first direction. Since the fixing component 34 is fixed to the housing 20 at this stage, it may also be regarded that the stop structure 354 stops the electronic device 30 from leaving the housing 20 along the second direction (herein, exemplified by the −Y direction) opposite to the first direction. Thereby, the stop structure 354 can provide a limiting function parallel to the first direction for the electronic device 30 (i.e., limiting the electronic device 30 in the direction parallel to the first direction), and the limiting component 32 can provide a limiting function perpendicular to the first direction for the electronic device 30 (i.e., limiting the limiting component 32 in the direction perpendicular to the first direction), so that the electronic device 30 can be fixed to the housing without using screws. Therefore, the drawbacks caused by the screw locking method, such as the strip of the screw, the damage of electronic device 30 caused by the strip of the screw, and the time-consuming assembly, can be avoided.

Specifically, the electronic apparatus may be an electronic apparatus equipped with at least one electronic device. For example, the electronic apparatus may be equipped with the electronic device 30 and may optionally be equipped with other electronic devices. The number of the electronic device 30 and the number of other electronic devices may independently be single or multiple. For example, the electronic apparatus may be a personal computer or a server, and the electronic device 30 may be one of the electronic devices of the personal computer or the server, such as a power supply, a memory or a fan, but not limited thereto. The types and the number of the electronic devices 30 may be adjusted according to the type of the electronic apparatus. For the sake of convenience for explanation, in this embodiment, the electronic device 30 is a fan, and the housing 20 is an exclusive housing for the fan of the electronic apparatus. However, it is only exemplary, and the present disclosure is not limited thereto.

The housing 20 may include a back plate 210, a top plate 212, a bottom plate 214 and a side plate 216. The back plate 210, the top plate 212, the bottom plate 214 and the side plate 216 together define an accommodation space 228 for accommodating the electronic device 30. The back plate 210 is formed with a hollow portion 218 and fitting portions 220. The hollow portion 218 includes a plurality of through holes (not labeled) corresponding to the fan for allowing the airflow generated by the fan to pass through. The fitting portion 220 is configured for the second portion 322 of the limiting component 32 to be embedded therein, so as to provide the limiting function perpendicular to the first direction for the limiting component 32. The number of the fitting portions 220 corresponds to the number of the limiting components 32. Herein, the number of the limiting components 32 is four, the number of the fitting portions 220 is four, and the four fitting portions 220 are located at four corners of the back plate 210. Herein, the fitting portion 220 is exemplarily a through hole.

The top plate 212 and the bottom plate 214 may further be formed with second engaged portions 222. When the electronic device 30 is in the fixed position (see FIG. 1), the second engaged portion 222 and the first engaged portion 362 of the limiting component 32 can be engaged with each other. Herein, the second engaged portion 222 is exemplarily a groove.

The electronic device 30 has a first surface S1 and a second surface S2 opposite to each other in the first direction. When the electronic device 30 is in the fixed position, the stop structure 354 abuts the first surface S1, and the back plate 210 of the housing 20 abuts the second surface S2, which may prevent the electronic device 30 from moving along the direction parallel to the first direction (i.e., moving along the first direction and the second direction). The electronic device 30 is formed with fitting portions 310 at a side thereof facing the limiting component 32. The fitting portion 310 is configured for the first portion 320 of the limiting component 32 to be embedded therein, so as to provide a limiting function perpendicular to the first direction for the limiting component 32. The number of the fitting portions 310 corresponds to the number of the limiting components 32. Herein, the number of fitting portions 310 is four, and the four fitting portions 310 are located at four corners of the side of the electronic device 30 facing the limiting components 32. Herein, the fitting portion 310 is exemplarily a through hole.

Herein, the fixing component 34 is exemplarily a spring piece, i.e., a sheet structure with elasticity. The fixing component 34, for example, may be made of a metal, a plastic or other materials that can provide elasticity. In this embodiment, the fixing component 34 may include a support plate 342 and two clamping plates 344 oppositely disposed at the upper end and the lower end of the support plate 342, and may optionally include two side plates 346 oppositely disposed at the left end and the right end of the support plate 342.

The support plate 342 is configured for being abutted by the second surface S2 of the electronic device 30. The support plate 342 is formed with a hole 340 and fitting portions 352. The hole 340 corresponds to the fan and is configured for allowing the airflow generated by the fan to pass through. The fitting portion 352 is configured for the limiting component 32 to be embedded therein, so as to provide a limiting function perpendicular to the first direction for the limiting component 32. The number of the fitting portions 352 corresponds to the number of the limiting components 32. Herein, the number of the fitting portions 352 is four, and the four fitting portions 352 are located at four corners of the support plate 342. Herein, the fitting portion 352 is exemplarily a through hole. It should be noticed that the numbers and the disposed positions of the aforementioned fitting portions and the aforementioned limiting components are exemplarily and the present disclosure is not limited thereto. For example, the number of the fitting portions may be two, the fitting portions are respectively located at the diagonal corners of the support plate, and the number of the of the limiting components may also be two, but not limited thereto.

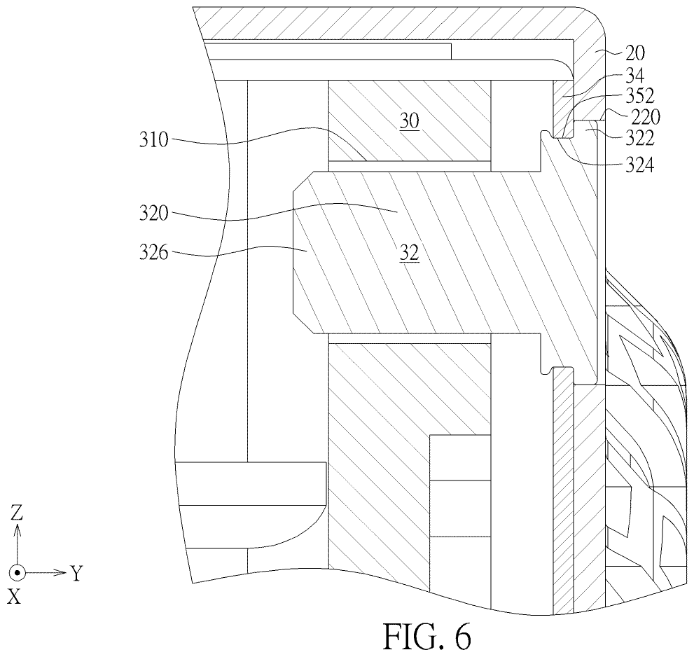

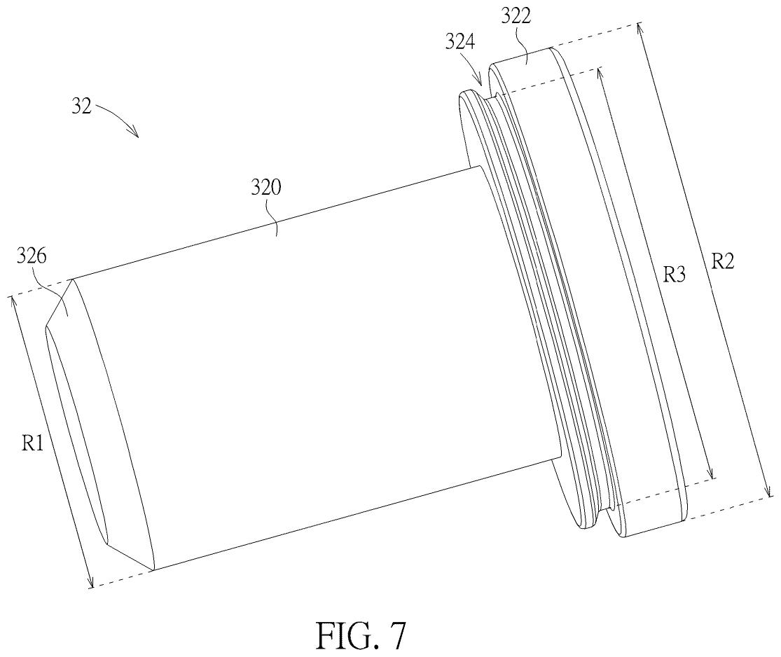

Please refer to FIG. 6 and FIG. 7, FIG. 6 is an enlarged cross-sectional schematic view taken along line A-A′ in FIG. 1. FIG. 7 is a three-dimensional schematic view of the limiting component 32 in FIG. 1. The limiting component 32 includes the first portion 320 and the second portion 322. The first portion 320 is a rod structure. The second portion 322 is a cap structure, and the second portion 322 includes an annular groove 324. The annular groove 324 is disposed at a side of the second portion 322 adjacent to the first portion 320. The fixing component 34 is correspondingly embedded in the annular groove 324, so that the limiting component 32 can be fixed to the fixing component 34. With the annular groove 324, the displacement of the limiting component 32 relative to the fixing component 34 in the direction parallel to the first direction can be limited.

The first portion 320 has a diameter R1, the second portion 322 has a diameter R2, the limiting component 32 has a diameter R3 corresponding to the annular groove 324, the diameter R2 is larger than the diameter R3, and the diameter R3 is larger than the diameter R1. In this embodiment, the aperture of the fitting portion 220 of the housing 20 is substantially equal to diameter R2, or the aperture of the fitting portion 220 of the housing 20 is slightly larger or slightly smaller than the diameter R2. The aperture of the fitting portion 352 of the fixing component 34 is substantially equal to the diameter R3, or the aperture of the fitting portion 352 of the fixing component 34 is slightly larger or slightly smaller than the diameter R3. The aperture of the fitting portion 310 of the electronic device 30 is substantially equal to the diameter R1, or the aperture of the fitting portion 310 of the electronic device 30 is slightly larger or slightly smaller than the diameter R1. Thereby, when the electronic device 30 is in the fixed position, there is no gap or almost no gap between the limiting component 32 and the fitting portions 220, 352 and 310, which is beneficial to limit the displacement of the limiting component 32 in the direction perpendicular to the first direction.

The limiting component 32 may further include a narrow portion 326 disposed at an end of the first portion 320 away from the second portion 322, and the diameter of the narrow portion 326 gradually decreases along a direction away from the second portion 322. Thereby, when assembling the electronic assembly 3, it is beneficial to reduce the accuracy required for aligning the fitting portion 310 of the electronic device 30 and the limiting component 32, so that the assembly efficiency can be enhanced.

Please refer to FIG. 1 and FIG. 2 again. The two side plates 346 are bent relative to the support plate 342 to assist in limiting the lateral displacement of the electronic device 30 relative to the fixing component 34 in the direction perpendicular to the first direction (i.e., the displacement parallel to the X-axis direction).

The two clamping plates 344 are bent relative to the support plate 342. Each of the clamping plates 344 includes a fixed end 368 and a free end 369 opposite to each other. The fixed end 368 is connected to the support plate 342. Each of the clamping plate 344 may deflect upward and downward relative to the support plate 342 (herein, exemplified by deflecting along the Z-axis direction) with the fixed end 368 being a pivot axis. Each of the clamping plates 344 may include a flexible body 341 and a movable arm 348. The movable arm is integrally connected to the flexible body 341 and is capable of deflecting relative to the flexible body 341 (herein, exemplified by capable of deflecting along the Z-axis direction). Specifically, the movable arm 348 extends outward from the flexible body 341 along the second direction, and a gap G is formed between the movable arm 348 and the flexible body 341.

Each of the two clamping plates 344 may be disposed with the stop structures 354. The stop structure 354 is disposed on the flexible body 341, and the stop structure 354 is away from the fixed end 368 (i.e., closer to the free end 369). Thereby, the flexible body 341 is capable of deflecting relative to the electronic device 30 to bring the stop structure 354 to abut or stop abutting the electronic device 30 in a labor-saving manner. The stop structure 354 is disposed on the surface S3 of the clamping plate 344 facing inward. The stop structure 354 may include a guiding portion 356 and a stop portion 358 disposed sequentially along the first direction, and an inclined degree of the guiding portion 356 is smaller than an inclined degree of the stop portion 358. The aforementioned “an inclined degree of the guiding portion 356” may refer to the degree that the guiding portion 356 inclines relative to the surface S3. The aforementioned “an inclined degree of the stop portion 358” may refer to the degree that the stop portion 358 inclines relative to the surface S3.

Each of the two clamping plates 344 may further include operated portions 360 disposed on the flexible body 341. Herein, the operated portion 360 may be integrally formed on the flexible body 341. The operated portion 360 is capable of being operated to bring the flexible body 341 to deflect relative to the electronic device 30, so as to bring the stop structure 354 to stop abutting the electronic device 30. For this part, references may be made to the relevant description below.

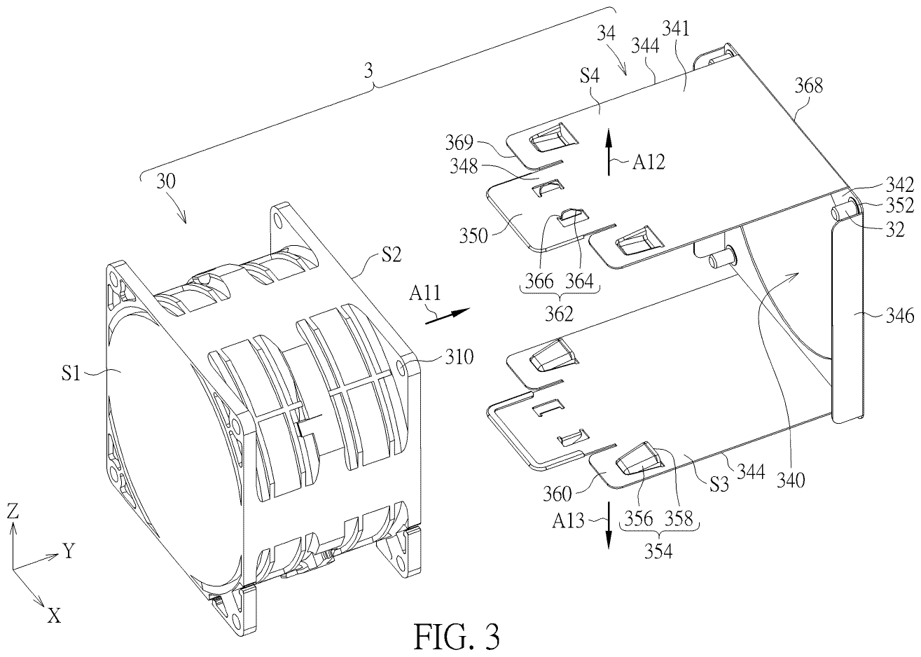

Each of the two clamping plates 344 may be further disposed first engaged portions 362. The first engaged portion 362 is disposed on the movable arm 348, and the first engaged portion 362 is capable of deflecting upward and downward relative to the flexible body 341 along with the movable arm 348. The first engaged portion 362 is disposed on the surface S4 of the clamping plate 344 facing outward. Herein, the first engaged portion 362 is exemplarily a hook, and the hook may include a guiding portion 364 (see FIG. 3) and a stop portion 366 (see FIG. 3) sequentially disposed along the second direction, and an inclined degree of the guiding portion 364 is smaller than the inclined degree of the stop portion 366. The aforementioned “an inclined degree of the guiding portion 364” may refer to the degree that the guiding portion 364 inclines relative to the surface S4. The aforementioned “an inclined degree of the stop portion 366” may refer to the degree that the stop portion 366 inclines relative to the surface S4.

In this embodiment, the first engaged portion 362 is a hook, and the second engaged portion 222 is a groove, but not limited thereto. In other embodiments, the first engaged portion 362 may be a groove, the second engaged portion 222 may be a hook, and the hook may can be disposed on each of the surfaces of the top plate 212 and the bottom plate 214 facing inward, which can also achieve the engagement between the first engaged portion 362 and the second engaged portion 222. In other words, embodiments that one of the first engaged portion 362 and the second engaged portion 222 is a hook and the other one of the first engaged portion 362 and the second engaged portion 222 is a groove are all within the scope of the present disclosure.

Each of the two clamping plates 344 may further include a disengaging portion 350 disposed on the movable arm 348. Herein, the disengaging portion 350 may be integrally formed on the movable arm 348. As shown in FIG. 1, when the electronic device 30 is in the fixed position, the disengaging portion 350 protrudes from the housing 20 in the first direction. The disengaging portion 350 is capable of being operated to bring the movable arm 348 to deflect relative to the housing 20, so as to bring the first engaged portion 362 to disengage from the second engaged portion 222. For this part, references may be made to the relevant description below.

In this embodiment, the stop structure 354 may be integrally formed on the flexible body 341, and the first engaged portion 362 may be integrally formed on the movable arm 348. For example, the stamping may be performed to form the stop structures 354 and the first engaged portions 362 respectively on the flexible body 341 and the movable arm 348. Thereby, it is beneficial to reduce the number of the elements of the fixing component 34. Furthermore, the entire fixing component 34 can be formed by stamping. For example, a metal spring piece can be provided, and then the stamping is performed to shear, bend and shape the metal spring piece to obtain the fixing component 34. That is, the fixing component 34 is a one-piece structure. Thereby, it is beneficial to simplify the manufacturing process of the fixing component 34, and the number of elements of the fixing component 34 can be further reduced.

In this embodiment, the number of stop structures 354 is four, the number of first engaged portions 362 is four, and each of the upper clamping plate 344 and the lower clamping plate 344 is disposed with two stop structures 354 and two first engaged portions 362. The number of the second engaged portions 222 is also four, which corresponds to the number of first engaged portions 362. The number of the limiting components 32 is four, and the numbers of fitting portions 220, 310 and 352 are all four, which correspond to the number of limiting components 32. However, it is only exemplary, and the present disclosure is not limited thereto. For example, in other embodiments, each of the upper clamping plate 344 and the lower clamping plate 344 may be disposed with one stop structure 354 and one first engaged portion 362. As another example, the number of the limiting components 32 may be two, and the two limiting components 32 may be disposed diagonally at the electronic device 30, the fixing component 34 and the housing 20. In other words, the number and the disposed position of each of the aforementioned components can be flexibly adjusted according to actual needs.

The method of installing the electronic device 30 in the housing 20 is explained as follows. First, the assembly of the electronic assembly 3 is completed, and then the electronic assembly 3 is installed in housing 20. Please refer to FIG. 3. First, the limiting components 32 are installed in the fixing component 34. Herein, the limiting components 32 are inserted through the fitting portions 352, and the fixing component 34 is embedded in the annular grooves 324 (see FIG. 7) of the limiting components 32, so that the limiting components 32 are fixed to the fixing component 34. The installation of the limiting components 32 in the fixing component 34 only needs to be done once. After that, the limiting components 32 can remain installed in the fixing component 34.

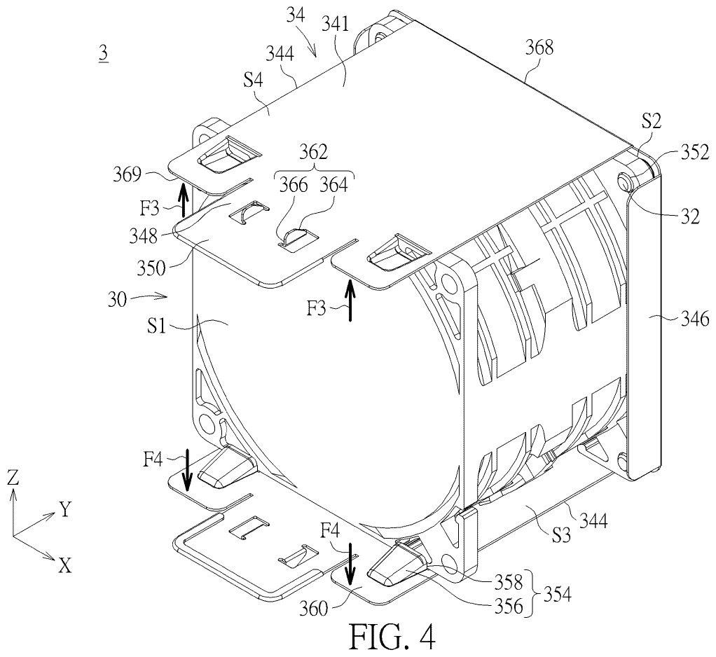

Next, the electronic device 30 is installed in the fixing component 34 along the direction of the arrow A11 (i.e., the first direction). In the process of moving the electronic device 30, when the electronic device 30 contacts the guiding portions 356 of the stop structures 354, the electronic device 30 pushes against the guiding portions 356, so that the flexible body 341 located above deflects along the direction of the arrow A12 (herein, exemplified by the +Z direction) and the flexible body 341 located below deflects along the direction of the arrow A13 (herein, exemplified by the −Z direction). When the electronic device 30 is continued to move along the direction of the arrow A11 to leave the guiding portions 356 and to contact the stop portions 358, the elastic force of the flexible body 341 brings the flexible body 341 located above to deflect along a direction opposite to the direction of the arrow A12 and the flexible body 341 located below to deflect along the direction opposite the direction of the arrow A13, so that the upper and the lower flexible bodies 341 return to the original positions thereof. At the same time, the first portions 320 of the limiting components 32 are correspondingly embedded into the fitting portions 310 of the electronic device 30. As shown in FIG. 4, when the assembly of the electronic assembly 3 is completed, the stop structures 354 abuts the first surface S1 of the electronic device 30, so that the electronic device 30 can be prevented from leaving the fixing component 34 along the second direction, and the limiting components 32 can limit the displacement of the electronic device 30 in a direction perpendicular to the first direction.

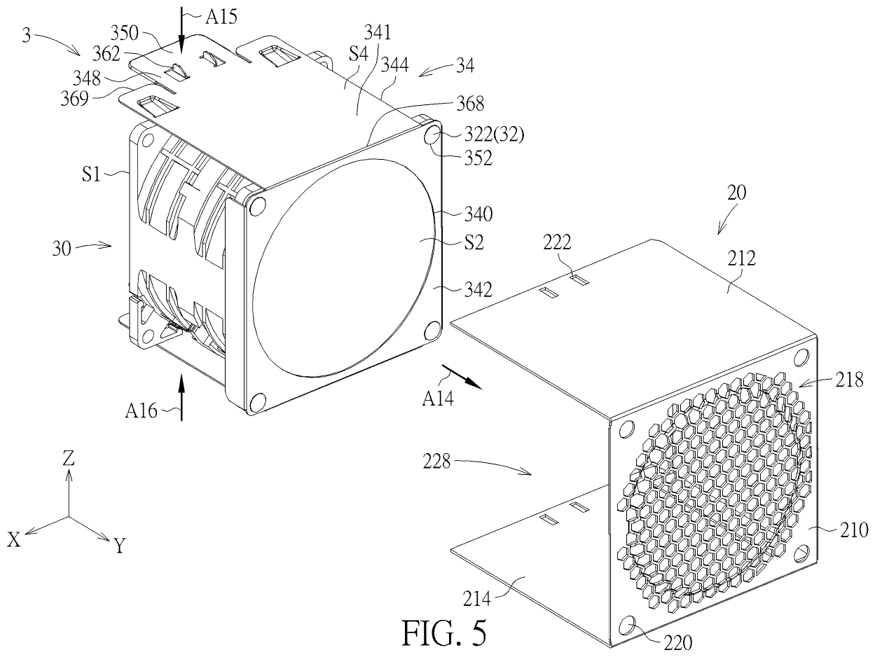

Next, as shown in FIG. 5, the electronic assembly 3 is installed in the housing 20 along the direction of the arrow A14 (i.e., the first direction). In the process of moving the electronic assembly 3, when the guiding portions 364 (see FIG. 4) of the first engaged portions 362 of the electronic assembly 3 contacts the housing 20, the guiding portions 364 are pushed by the housing 20, so that the movable arm 348 located above deflects along the direction of the arrow A15 (herein, exemplified by the −Z direction) and the movable arm 348 located below deflects along the direction of the arrow A16 (herein, exemplified by the +Z direction). When the electronic assembly 3 is continued to move to allow the first engaged portions 362 to begin to enter the second engaged portions 222 (herein, the hooks begin to enter the grooves), the elastic force of the movable arm 348 brings the movable arm 348 located above to deflect in the direction opposite to the direction of the arrow A15 and the movable arm 348 located below to deflect in the direction opposite to the direction of the arrow A16. After the first engaged portions 362 completely enter into the second engaged portions 222 (herein, the hooks completely enter into the grooves), the upper and the lower movable arms 348 return to the original positions thereof. At this stage, the first engaged portion 362 is engaged with the second engaged portion 222, and the second portion 322 of the limiting component 32 is embedded in the fitting portion 220 of the housing 20 correspondingly. As shown in FIG. 1, when the assembly of electronic assembly 3 and the housing 20 is completed, the first engaged portion 362 and the second engaged portion 222 are engaged with each other, the stop portion 366 (see FIG. 4) of the first engaged portion 362 abuts the housing 20 to prevent the electronic assembly 3 from leaving the housing 20 along the second direction, and the limiting component 32 limits the displacement of the electronic assembly 3 in the direction perpendicular to the first direction.

When the electronic device 30 is required to be repaired or replaced, the disassembly method is explained as follows. Please refer to FIG. 1. A downward force F1 and an upward force F2 can be respectively applied to the upper and the lower disengaging portions 350, so that the upper and the lower disengaging portions 350 respectively deflect downward and upward to bring the first engaged portions 362 to disengage from the second engaged portions 222, and then the electronic assembly 3 is pulled away from the housing 20 along the second direction, so that the electronic assembly 3 can be disassembled from the housing 20. Next, please refer to FIG. 4. An upward force F3 and a downward force F4 may be respectively applied to the upper and the lower operated portions 360 to bring the upper and the lower flexible bodies 341 to respectively deflect upward and downward, which may bring the stop structures 354 to stop abutting the electronic device 30. Then the electronic device 30 is pulled away from the fixing component 34 along the second direction, so that the electronic device 30 can be disassembled from the fixing component 34, as shown in FIG. 3.

According to the above description, the flexible body 341 of the present disclosure is capable of deflecting relative to the electronic device 30 to bring the stop structure 354 to abut or stop abutting the electronic device 30. The movable arm 348 of the present disclosure is capable of deflecting relative to the housing 20 to bring the first engaged portion 362 to engage with or disengage from the second engaged portion 222.

According to the above description, in the present disclosure, the electronic device 30 is fixed to the housing 20 through the limiting component 32 and the fixing component 34 without using screws for locking. It is easy to assemble, so that the quick assembly can be achieved. When disassembling the electronic device 30, it only needs to apply an upward force or a downward force on the disengaging portion 350 and the operated portion 360 and cooperate with the pulling movement, and the electronic device 30 can be disassembled from the housing 20. There is no need to remove the locking screws one by one. It is easy to disassemble, so that the quick disassembly can be achieved. In addition, with the gap G formed between the movable arm 348 and the flexible body 341, it is beneficial to reduce the force required to deflect the disengaging portion 350 during disassembling, so that the effect of labor-saving can be further achieved.

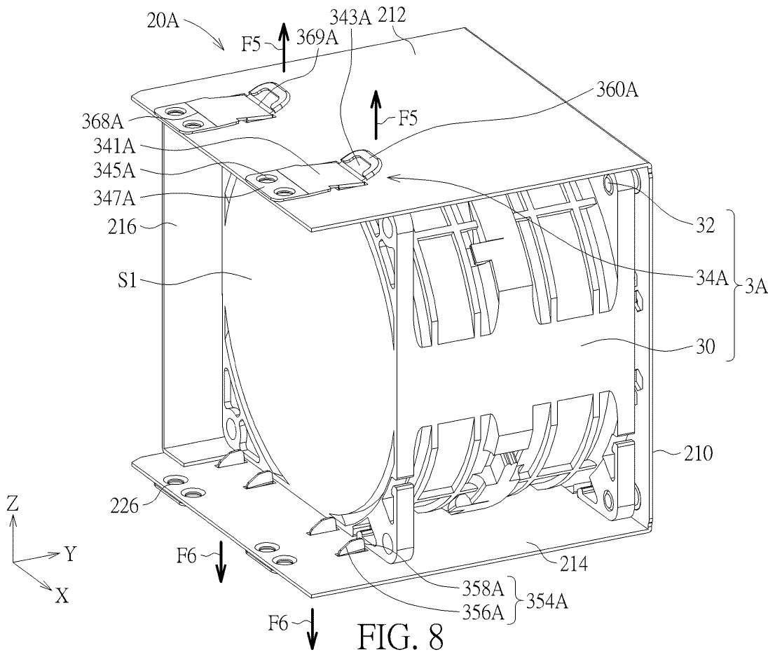

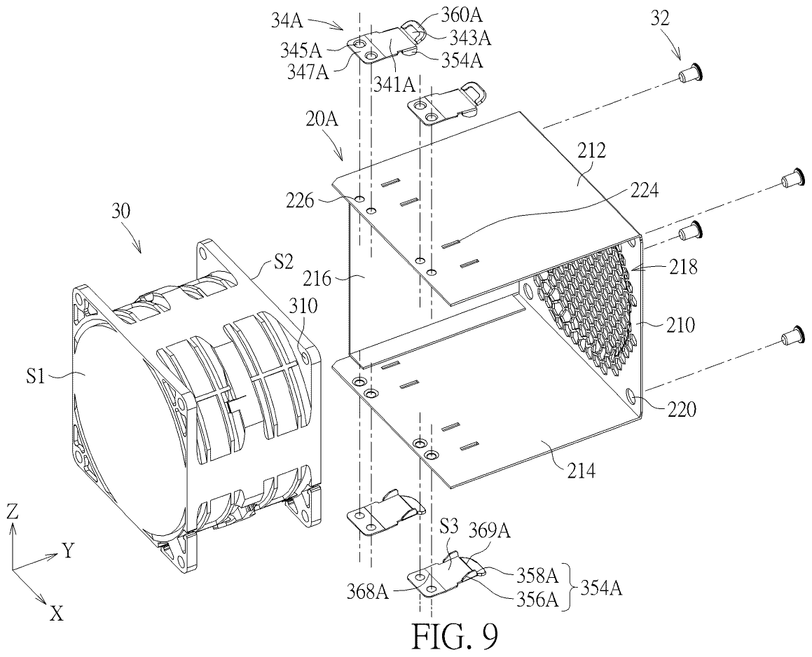

Please refer to FIG. 8 and FIG. 9. FIG. 8 is a three-dimensional schematic view of an electronic assembly 3A and a housing 20A in an assembling state according to another embodiment of the present disclosure. FIG. 9 is an exploded schematic view of the electronic assembly 3A and the housing 20A in FIG. 8. The differences between the electronic assembly 3A and the electronic assembly 3 are that the structures of the fixing component 34A and the housing 20A are different from the structures of the fixing component 34 and the housing 20.

In this embodiment, the electronic assembly 3A includes four fixing components 34A. Each of the fixing components 34A may include a flexible body 341A, a fixed portion 347A and an operated portion 360A. The fixed portion 347A is disposed at the fixed end 368A of the flexible body 341A, and the operated portion 360A is disposed at the free end 369A of the flexible body 341A. That is, the fixed portion 347A, the flexible body 341A and the operated portion 360A may be disposed sequentially along the first direction.

The fixing component 34A is fixed to the housing 20A through the fixed portion 347A. Herein, the fixed portion 347A exemplarily includes two blind rivet structures 345A, and the housing 20A is formed with two holes 226 corresponding to the blind rivet structures 345A for the blind rivet structures 345A being fixed thereto, but not limited thereto. The fixing component 34A may be fixed to the housing 20A through other fixing means such as riveting and welding.

The flexible body 341A may be made of a metal, a plastic or other material that can provide elasticity. The flexible body 341A includes a fixed end 368A and a free end 369A opposite to each other. The fixed end 368A is connected to the fixed portion 347A. Each of the flexible bodies 341A is capable of deflecting upward and downward relative to fixed portion 347A or the housing 20 (herein, exemplified by capable of deflecting along the Z-axis direction) with the fixed end 368 being a pivot axis.

Each of the fixing components 34A may include a stop structure 354A protruding from the surface S3 of the fixing component 34A perpendicularly to the first direction. Specifically, the stop structure 354A is disposed on the flexible body 341A, and the stop structure 354A is away from the fixed end 368A (i.e., closer to the free end 369A). Thereby, the flexible body 341A is capable of deflecting relative to the electronic device 30 to bring the stop structures 354A to abut or stop abutting the electronic device 30 in a labor-saving manner. In other words, one end of the fixing component 34A is fixed to the housing 20A, and the other end of the fixing component 34 A is disposed with the stop structures 354A.

The stop structures 354A are disposed on the surface S3 of the flexible body 341A facing inward. Herein, the stop structures 354A are integrally formed on the flexible body 341A, and are bent from two sides of the flexible body 341A to protrude from the surface S3 of the fixing component 34A along a direction perpendicular to the first direction. The stop structure 354A may include a guiding portion 356A and a stop portion 358A sequentially disposed along the first direction, and an inclined degree of the guiding portion 356A is smaller than an inclined degree of the stop portion 358A.

The operated portion 360A may be bent relative to the flexible body 341A away from the surface S3. The operated portion 360A is disposed on the flexible body 341A and is capable of deflecting relative to the flexible body 341A. For example, the operated portion 360A is capable of deflecting relative to flexible body 341A with the free end 369A of the flexible body 341A being a pivot axis. The operated portion 360A is capable of being operated to bring the flexible body 341A to deflect relative to the electronic device 30, so as to bring the stop structure 354A to stop abutting the electronic device 30. For this part, references may be made to the relevant description below. The connecting portion 343A is connected between the operated portion 360A and the flexible body 341A. The entire fixing component 34A is a sheet metal component and is folded at the operated portion 360A to avoid cuts caused by excessively sharp edges of the sheet metal component.

The housing 20A includes grooves 224. The grooves 224 correspond to the stop structures 354A. When the electronic device 30 is in a fixed position, as shown in FIG. 8, the stop structure 354A passes through the groove 224 to abut the electronic device 30.

In this embodiment, the stamping may be performed to form the stop structures 354A on the flexible body 341A. Thereby, it is beneficial to reduce the number of the elements of the fixing component 34A. Furthermore, the entire fixing component 34A can be formed by stamping. For example, a metal spring piece can be provided, and then the stamping is performed to shear, bend and shape metal spring piece to obtain the fixing component 34A. The blind rivet structures 345A of the fixing component 34A are formed when fixing the fixing component 34A to the housing 20A. That is, the fixing component 34 is a one-piece structure. Thereby, it is beneficial to simplify the manufacturing process of the fixing component 34A, and the number of elements of the fixing component 34 can be further reduced.

In this embodiment, the number of fixing components 34A is four, two of the fixing components 34A are disposed on the top plate 212 of housing 20A, and the other two of the fixing components 34A are disposed on the bottom plate 214 of housing 20A. Each of the fixing components 34A has two stop structures 354A and two blind rivet structures 345A. The number of the limiting components 32 is four, and the numbers of the fitting portions 220 and 310 are also four, which correspond to the number of limiting components 32. However, it is only exemplary, and the present disclosure is not limited thereto. For example, in other embodiments, each of the top plate 212 and the bottom plate 214 may only be disposed with one fixing component 34A, and each of the fixing components 34A may only be disposed with one stop structure 354A and one blind rivet structure 345A. As another example, in other embodiments, the number of limiting components 32 may be two, and the two limiting components 32 may be disposed diagonally at the electronic device 30 and the housing 20A.

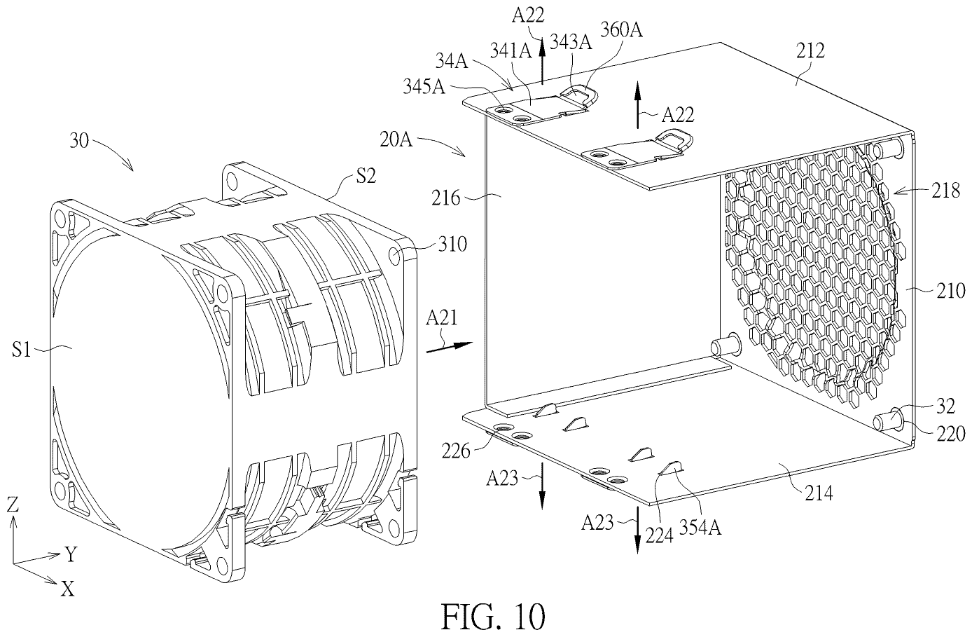

The method of installing the electronic device 30 in the housing 20A is explained as follows. As shown in FIG. 10, first, the limiting components 32 and the fixing components 34A are installed on the housing 20A. Herein, the second portions 322 (see FIG. 7) of the limiting components 32 are embedded in the fitting portions 220 of the housing 20A. The housing 20A is correspondingly embedded in the annular grooves 324 (see FIG. 7) of the limiting components 32, so that the limiting components 32 are fixed to the housing 20A, and the fixing components 34A are fixed to the holes 226 of the housing 20A by a rivet tool (such as a rivet gun) to form the blind rivet structures 345A. In addition, the stop structures 354A correspondingly passes through the grooves 224 to protrude from the surfaces of the top plate 212 and the bottom plate 214 face inward. The installation of the limiting components 32 and the fixing components 34A on the housing 20A only needs to be done once. After that, the limiting components 32 and the fixing components 34A can remain installed on the housing 20A.

Next, the electronic device 30 is installed in the housing 20A along the direction of the arrow A21 (i.e., the first direction). In the process of moving the electronic device 30, when the electronic device 30 contacts the guiding portions 356A (see FIG. 9) of the stop structures 354A, the electronic device 30 pushes against the guiding portions 356A, so that the flexible body 341A located above deflects along the direction of the arrow A22 (herein, exemplified by the +Z direction) and the flexible body 341A located below deflects along the direction of the arrow A23 (herein, exemplified by the −Z direction). When the electronic device 30 is continued to move along the direction of the arrow A21 to leave the guiding portions 356A and to contact the stop portions 358A, the elastic force of the flexible body 341A brings the flexible body 341A located above to deflect along a direction opposite to the direction of the arrow A22 and the flexible body 341A located below to deflect along the direction opposite the direction of the arrow A23, so that the upper and the lower flexible bodies 341A return to the original positions thereof. At the same time, the first portions 320 of the limiting components 32 are correspondingly embedded into the fitting portions 310 of the electronic device 30.

According to the above description, when the electronic device 30 is installed in the housing 20A along the first direction and is in the fixed position, as shown in FIG. 8, the first portion 320 of the limiting component 32 is embedded in the electronic device 30, the second portion 322 of the limiting component 32 is embedded in the housing 20A, and the stop structure 354A stops the electronic device 30 from leaving the fixing component 34A along the second direction opposite to the first direction. That is, the stop structure 354A stops the electronic device 30 from leaving the housing 20A along the second direction opposite to the first direction. In addition, when the electronic device 30 is in the fixed position, the stop structure 354A abuts the first surface S1 of the electronic device 30, and the housing 20A abuts the second surface S2 of the electronic device 30.

When the electronic device 30 is required to be repaired or replaced, the disassembly method is explained as follows. Please refer to FIG. 8. An upward force F5 and a downward force F6 may be respectively applied to the upper and the lower operated portions 360A to bring the upper and the lower flexible bodies 341A to respectively deflect upward and downward, which may bring the stop structures 354A to stop abutting the electronic device 30. Then the electronic device 30 is pulled away from the housing 20A along the second direction, so that the electronic device 30 can be disassembled from the housing 20A, as shown in FIG. 10. In the present disclosure, when the electronic device 30 is disassembled, the upward force F5 and the downward force F6 applied to the upper and lower operated portions 360A can simply be provided with bare hands, and other tools are not required.

According to the above description, in the present disclosure, the electronic device 30 is fixed to the housing 20A through the limiting component 32 and the fixing component 34A without using screws for locking. It is easy to assemble, so that the quick assembly can be achieved. When disassembling the electronic device 30, it only needs to apply an upward force or a downward force on the operated portion 360A and cooperate with the pulling movement, and the electronic device 30 can be disassembled from the housing 20A. There is no need to remove the locking screws one by one. It is easy to disassemble, so that the quick disassembly can be achieved.

In the two embodiments shown in FIG. 1 to FIG. 10, the electronic device 30 is a fan, and the housing 20 or 20A may be obtained by processing an exclusive housing for the fan provided by the electronic apparatus. The fitting portions 310 and 220 may be the original holes of the fan and the housing for the screws. With the screws, the fan can be fixed to the original housing. In the present disclosure, the screws are replaced by the limiting components 32 without the thread structures, the fixing component 34 or 34A is added, and then the original housing is processed to form the second engaged portion 222 corresponding to the fixing component 34 to form the housing 20, or the original housing is processed to form the grooves 224 and the holes 226 to form housing 20A. Thereby, the assembly without the screws can be achieved. In other words, the electronic assembly 3 and 3A according to the present disclosure can be applied to the existing electronic devices and the existing housings without eliminating the existing electronic devices and the existing housings. In this case, it is beneficial to reduce the manufacturing cost.

As mentioned above, the electronic device 30 being a fan is only exemplary. The electronic device 30 can be any electronic device in the electronic apparatus. In addition, the housing 20 or 20A being the exclusive housing for the fan of the electronic apparatus is only exemplary. When the electronic device 30 is an electronic device different from the fan, the housing 20 or 20A may also be the exclusive housing for the electronic device. In other embodiments, the electronic apparatus may only include a single housing, and the housing 20 or 20A may be part of the single housing. That is, the housing 20 or 20A may be integrally formed on the one-piece housing.

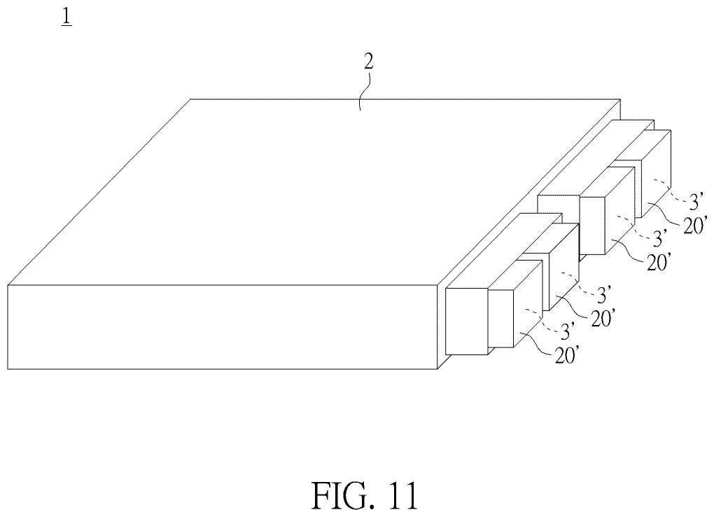

Please refer to FIG. 11, which is a three-dimensional schematic view of an electronic apparatus 1 according to yet another embodiment of the present disclosure. The electronic apparatus 1 includes housings 20′ and electronic assemblies 3′. The electronic assembly 3′ is installed in the housing 20′. The electronic assembly 3′ is mainly installed inside the housing 20′, so that the electronic assembly 3′ is shown by a dotted line. In this embodiment, the electronic apparatus 1 further includes a main housing 2. The housing 20′ is detachably disposed on the main housing 2. The numbers of the housings 20′ and the electronic assemblies 3′ are four. For example, the housing 20′ may be the exclusive housing for a fan, and the fan is disposed in the housing 20′ to provide the heat dissipating function for other electronic devices in the electronic apparatus 1. However, the present disclosure is not limited thereto. In other embodiments, the housing 20′ may be integrally formed on the main housing 2, and the housing 20′ may be an exclusive housing for other electronic devices. The number and the disposed position of the housing 20′ may also be flexibly adjusted according to actual needs. For example, the housing 20′ may be the housing 20. In this case, the electronic assembly 3′ may be the electronic assembly 3. Alternatively, the housing 20′ may be the housing 20A. In this case, the electronic assembly 3′ may be the electronic assembly 3A. For details about the electronic apparatus 1, the housing 20′ and the electronic assembly 3′, references may be made to the relevant descriptions of the electronic apparatus, the electronic assemblies 3 and 3A and the housings 20 and 20A above, and are omitted herein.

Compared with the prior art, in the present disclosure, the electronic assembly fixes the electronic device to the housing through the limiting component and the fixing component. Compared with the method of locking the electronic device to the housing by screws, the electronic assembly according to the present disclosure has the advantage of easy assembling and disassembling, and the damage of the electronic device due to the strip of the screw can be avoided.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An electronic assembly for being installed in a housing of an electronic apparatus, the electronic assembly comprising:
an electronic device;
a limiting component; and
a fixing component comprising a stop structure, wherein the stop structure protrudes from a surface of the fixing component perpendicularly to a first direction, when the electronic device is installed in the housing along the first direction and is in a fixed position, the limiting component is partially embedded in the electronic device and partially embedded in the housing, and the stop structure stops the electronic device from leaving the housing along a second direction opposite to the first direction.

2. The electronic assembly of claim 1, wherein the electronic device has a first surface and a second surface opposite to each other in the first direction, and when the electronic device is in the fixed position, the stop structure abuts the first surface, and the housing abuts the second surface.

3. The electronic assembly of claim 1, wherein the stop structure comprises a guiding portion and a stop portion disposed sequentially along the first direction, and an inclined degree of the guiding portion is smaller than an inclined degree of the stop portion.

4. The electronic assembly of claim 1, wherein the fixing component comprises a flexible body, the stop structure is disposed on the flexible body, and the flexible body is capable of deflecting relative to the electronic device to bring the stop structure to abut the electronic device or stop abutting the electronic device.

5. The electronic assembly of claim 4, wherein the stop structure is integrally formed on the flexible body.

6. The electronic assembly of claim 4, wherein the fixing component further comprises an operated portion disposed on the flexible body, and the operated portion is capable of being operated to bring the flexible body to deflect relative to the electronic device, so as to bring the stop structure to stop abutting the electronic device.

7. The electronic assembly of claim 6, wherein the operated portion is disposed on the flexible body and is capable of deflecting relative to the flexible body.

8. The electronic assembly of claim 6, wherein the operated portion is integrally formed on the flexible body.

9. The electronic assembly of claim 4, wherein the fixing component further comprises a first engaged portion, the housing comprises a second engaged portion, and when the electronic device is in the fixed position, the first engaged portion and the second engaged portion are engaged with each other.

10. The electronic assembly of claim 9, wherein one of the first engaged portion and the second engaged portion is a hook, and another one of the first engaged portion and the second engaged portion is a groove.

11. The electronic assembly of claim 10, wherein the hook comprises a guiding portion and a stop portion sequentially disposed along the second direction, and an inclined degree of the guiding portion is smaller than an inclined degree of the stop portion.

12. The electronic assembly of claim 9, wherein the fixing component further comprises a movable arm, the movable arm is integrally connected to the flexible body and is capable of deflecting relative to the flexible body, and the first engaged portion is disposed on the movable arm.

13. The electronic assembly of claim 12, wherein the fixing component further comprises a disengaging portion disposed on the movable arm, and the disengaging portion is capable of being operated to bring the movable arm to deflect relative to the housing, so as to bring the first engaged portion to disengage from the second engaged portion.

14. The electronic assembly of claim 13, wherein the disengaging portion is integrally formed on the movable arm, and when the electronic device is in the fixed position, the disengaging portion protrudes from the housing along the first direction.

15. The electronic assembly of claim 12, wherein a gap is formed between the movable arm and the flexible body.

16. The electronic assembly of claim 1, wherein the housing comprises a groove, and when the electronic device is in the fixed position, the stop structure passes through the groove to abut the electronic device.

17. The electronic assembly of claim 1, wherein an end of the fixing component is fixed to the housing, and another end of the fixing component is disposed with the stop structure.

18. The electronic assembly of claim 1, wherein the fixing component comprises a support plate and two clamping plates oppositely disposed at two ends of the support plate, the two clamping plates are bent relative to the support plate, and the stop structure is disposed on each of the two clamping plates.

19. The electronic assembly of claim 1, wherein the limiting component comprises an annular groove, and the fixing component or the housing is correspondingly embedded in the annular groove.

20. An electronic apparatus, comprising:
a housing; and
an electronic assembly installed in the housing, wherein the electronic assembly comprises:
an electronic device;
a limiting component; and
a fixing component comprising a stop structure, wherein the stop structure protrudes from a surface of the fixing component perpendicularly to a first direction, when the electronic device is installed in the housing along the first direction and is in a fixed position, the limiting component is partially embedded in the electronic device and partially embedded in the housing, and the stop structure stops the electronic device from leaving the housing along a second direction opposite to the first direction.
